(19) United States
(12) Patent Application Publication
(10) Pub. No.: US 2026/0013068 A1
(43) Pub. Date: Jan. 8, 2026

(54) FRONT-LOADING DRIVE CADDY AND LOCKING CHANNEL

(71) Applicant: Zoho Corporation Private Limited, Kanchipuram District (IN)

(72) Inventors: Devesh Laxmichand Khadgi, Nagpur (IN); Mangesh Devidas Sadafale, Nagpur (IN); Yash Manoj Kadu, Nagpur (IN); Nikhil Raghunath Mote, Tuljapur (IN); Animesh Anil Admane, Nagpur (IN)

(73) Assignee: Zoho Corporation Private Limited, Kanchipuram District (IN)

(21) Appl. No.: 19/258,698

(22) Filed: Jul. 2, 2025

Related U.S. Application Data
(60) Provisional application No. 63/683,202, filed on Aug. 14, 2024.

(30) Foreign Application Priority Data
Jul. 3, 2024 (IN) 202441051040

(51) Int. Cl. H05K 7/14; H05K 9/00

(52) U.S. Cl. CPC H05K 7/1489; H05K 9/0062

(57) ABSTRACT

A storage drive caddy has a unitary body having flexible feature defining a resiliently deformable region configured to permit displacement. Fixed to the flexible feature are a latch to lock in a locking channel and a handle to move the latch. First and second guiding sides connect to the drive via one or more screwless integrated mounting pins. Optionally symmetric side plates and one or more center wall plates are fixed with guides forming channels to house one or more columns of drive caddies. Modifications to channel widths and optional stopping mechanisms provide unidirectional caddy insertion. Conductive side and center wall plates attached to conductive top and bottom plates, along with conductive elements attached to each caddy, abutted from top plate to bottom plate, provide electromagnetic interference protection.

### CROSS REFERENCE TO RELATED APPLICATIONS

This application is related to Indian Provisional Application 20/244,1051040, filed 3 Jul. 2024, and U.S. Provisional Application 63/683,202 filed 14 Aug. 2024, both entitled “FRONT-LOADING DRIVE CADDY AND LOCKING CHANNEL”, both of which are incorporated herein by reference.

### FIELD OF THE INVENTION

Embodiments of the present disclosure are related, in general, to data servers and more particularly, but not exclusively, to drive caddies.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIG. 1A shows a first embodiment of a caddy 10 that receives and supports a hard drive.

FIG. 1B shows a first embodiment of an electromagnetic interference (EMI) cage 7 in its separate parts.

FIGS. 1C-E show various views of a second embodiment of an electromagnetic interference (EMI) cage.

FIGS. 1F-M illustrate aspects of a second embodiment of a caddy, including its coupling with an EMI cage.

FIGS. 2A and 2B illustrate server chassis plates, a sidewall 210 and a center wall 220, configured to receive a caddy 10.

FIG. 3 illustrates a portion of a server chassis 230 comprising two sidewalls 210 (one left and one right) and three center walls 220.

FIG. 4 illustrates an enclosure 300 formed by attaching a conductive top 240 and a conductive bottom 250 to the portion of server chassis 230.

FIGS. 5A and 5B show results of strength test analysis of the sidewall 210.

FIGS. 6A and 6B show results of strength test analysis of the center wall 220.

### DETAILED DESCRIPTION

Drive caddies, also known as drive trays or drive carriers, are essential components in server environments. They are used to house and secure hard drives (HDDs) or solid-state drives (SSDs), collectively “storage drives” or just “drives,” in a server chassis. Many servers support hot-swappable drives, allowing drives to be replaced or added without powering down the server.

Drive caddies are available for different form factors, typically 2.5-inch and 3.5-inch drives, matching the common sizes of HDDs and SSDs. By using appropriate drive caddies, server administrators can efficiently manage storage devices, ensuring reliability, ease of maintenance, and scalability in their server environments. A server chassis can be configured to house sets of caddies and can be customized to take advantage of the design features of the caddy.

A caddy is configured to house a storage drive with body having a crossmember and two guiding sides extending from the crossmember to connect to the drive with mounting pins integrated into the caddy body. No screws are required. A handle and latch are affixed to a flexible feature integrally formed in a recess in the caddy body, the flexible feature configured to flex relative to the caddy body about a connection region, moving the latch. This allows the latch to move to engage with a catch, and for the handle to be used to retract the latch to release it. A second handle affixed proximate to the second end of the crossmember partners with the first handle for easy insertion and removal of the caddy.

A stopping edges is placed at a predetermined distance from the mounting pins to determine the depth of a housed storage drive within the server chassis. A conductive element, adaptable to form part of an electromagnetic interference shield, is configured to couple with the crossmember of the caddy body. An optical element is disposed to receive source light at a first end and display the source light at a second end, which can be inserted into recess in a guiding side.

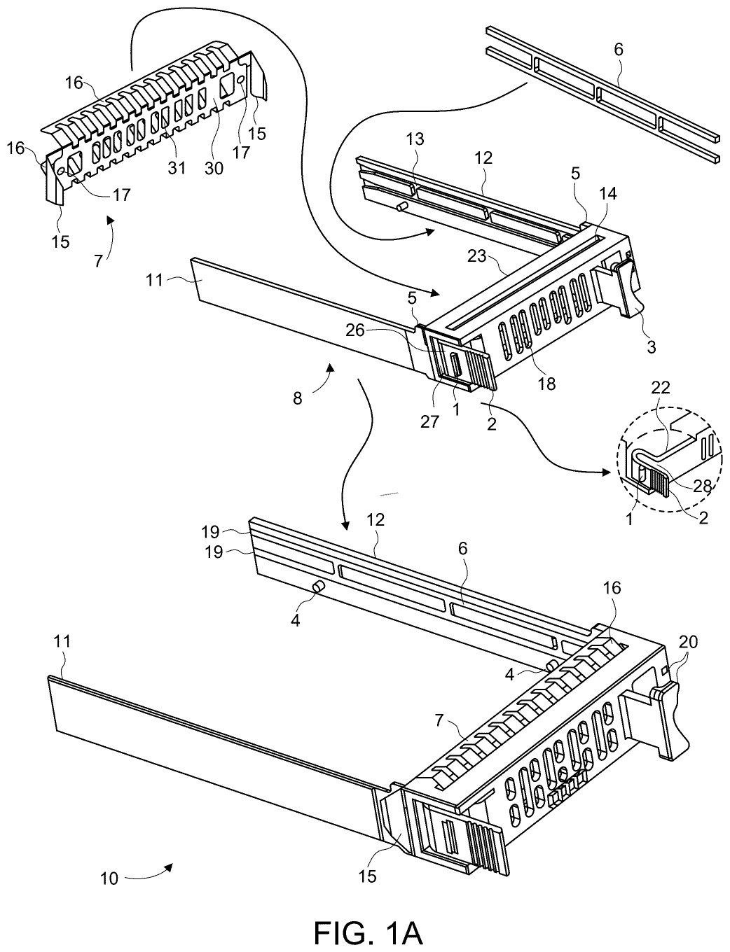

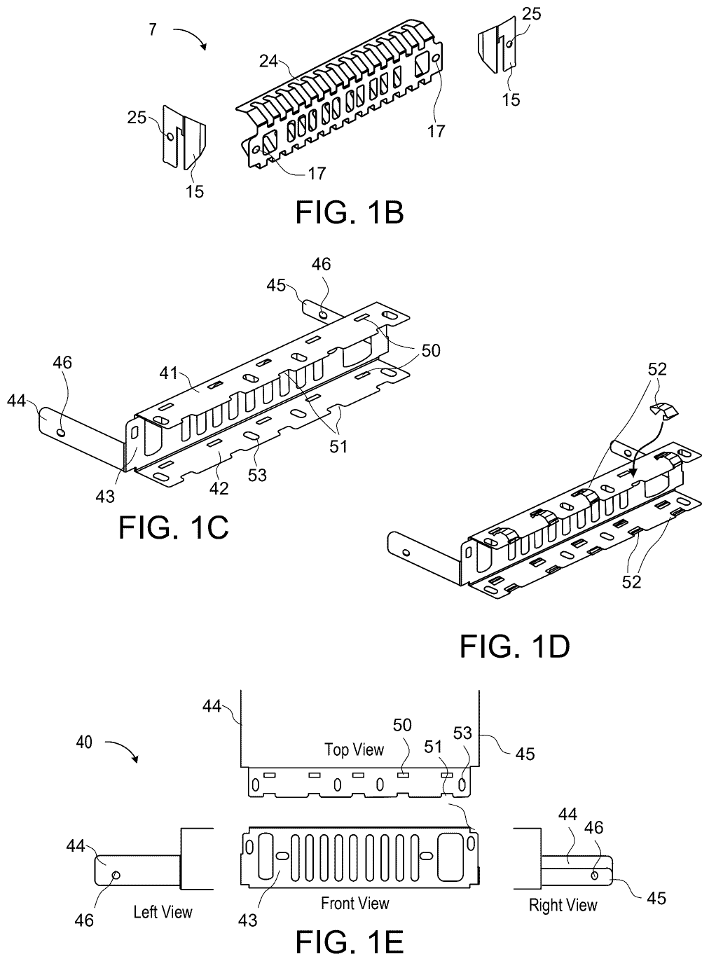

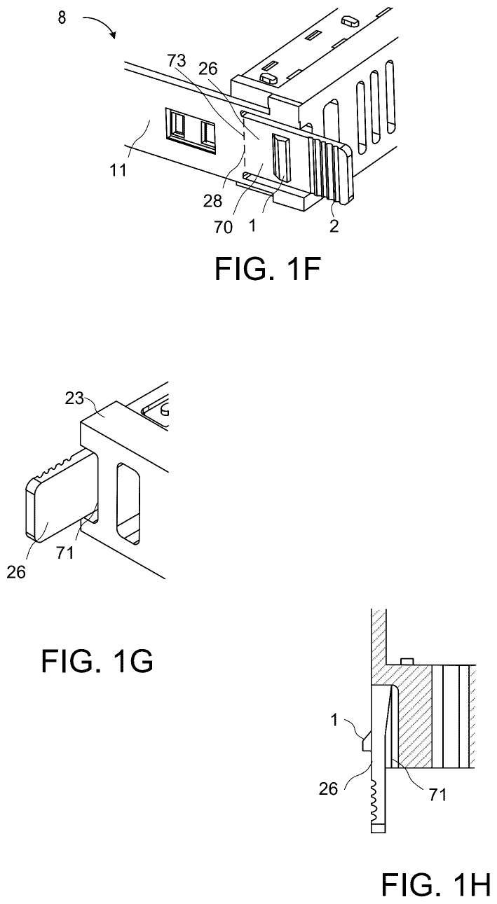

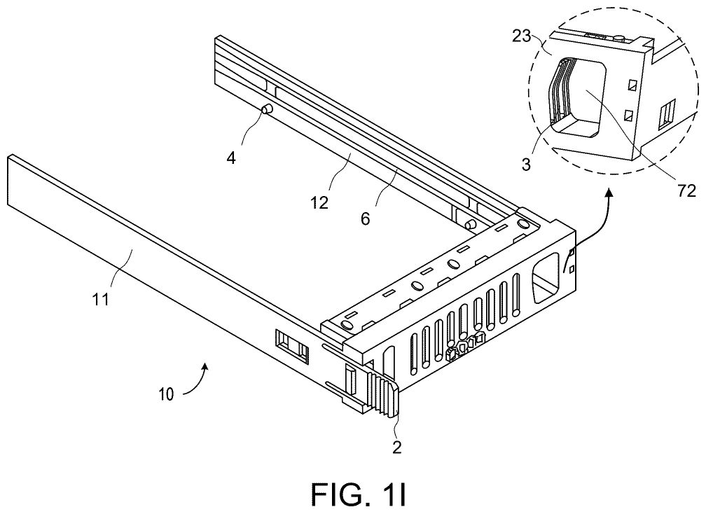

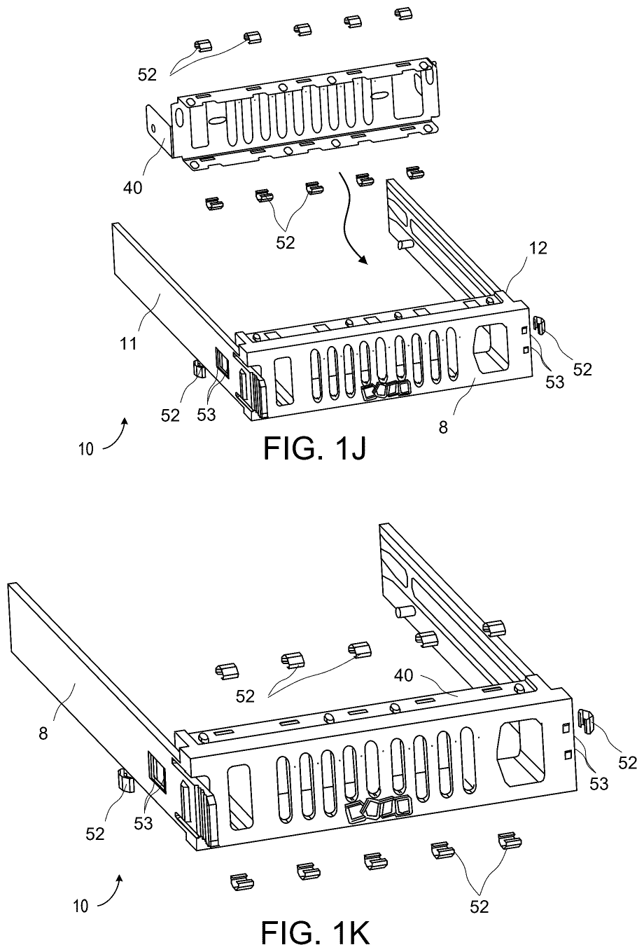

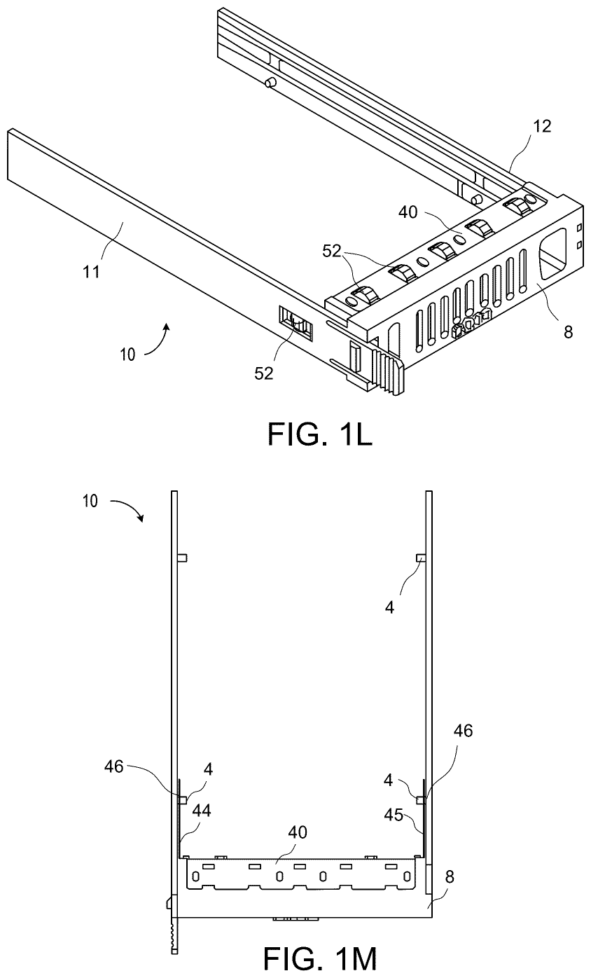

FIG. 1A depicts an embodiment of a drive caddy 10 that receives and supports a hard drive (not shown). One or more such drive caddies can be installed in a computer system, such as a server. The caddy is adapted to be inserted into a front-loading server chassis. The hot-swap, screwless, and springless design allows it to be inserted into the chassis achieving correct alignment, avoiding incorrect guiding which can lead to physical damage, data loss, and hardware failure. The caddy is a protective robust enclosure which safeguards the drive from physical damage. The need for additional tools or locking mechanisms is eliminated, reducing overall equipment costs. This embodiment has an inverted U bend that acts like a spring, used to catch and release a latch, eliminating the need for springs and reducing part complexity. In an embodiment, plastic material is used to reduce the overall weight of the caddy. Metal is added optionally for electromagnetic interference (EMI) protection. The caddy is designed to maintain enough airflow through the backplane for system cooling purposes. The features work together to provide a caddy that is lighter, cost-effective, and provides protection against shock and vibration.

FIG. 1A shows caddy 10 comprising three parts: a caddy body 8, an EMI cage 7, and an optical element 6. The caddy body 8 comprises a crossmember 23 and two sides 11 and 12. Sides 11 and 12 can be used as guides when inserting a caddy 10 into a channel in a server chassis. Mounting pins 4 extend inwardly from the sides 11 and 12 and are located such that the flexible sides can be extended outward to allow a hard drive to be inserted into the caddy (details omitted). The mounting pins 4 are located on the sides such that they can be inserted into the screw holes of the drive 40 and the drive is then securely in place in the caddy, with the two sides and the cross member 23 surrounding it. Thus, this screw-free mechanism is integrated into a protective enclosure for the drive.

Side 12 has a recess 13 embedded within it which can receive optical element 6. It can be inserted without tools or adhesive as shown. Optical inputs 19 can receive light from a source (typically server LED status lights in the example embodiment). Here two optical channels are able to receive two light inputs and the interference between them is minimal because the connections are right angles. The light through optical element 6 is visible at optical outputs 20, which are flush with the front of the caddy 10.

Cross member 23 comprises air vents 18 to allow air to pass through for heat dissipation. Self-locking handle 2 is formed in cross member 23 as a reverse U bend structure 22 as shown in the cutout. This is one example of a flexible feature 26, formed in a recess 27 within caddy body 8. The flexible feature 26, and thus self-locking handle 2 and latch 1 are free to move about the connection region 28, at which the flexible feature connects with the caddy body. It contains a latch (or lock) 1, which can be used in conjunction with a locking slot or catch in a server chassis (an example is detailed below). An angled latch 1 is provided which can automatically insert into a slot upon insertion of the caddy into a server chassis. A stationary handle 3 is provided which can be used with the self-locking handle 2 by applying pressure to the handles which will retract handle 2, allowing lock 1 to retract along with it, allowing the caddy to be removed. Releasing handle 2 allows the lock 1 and handle 2 to return to their original positions. Grips are provided on both handles 2 and 3 for securely inserting, removing, and holding a caddy and associated hard drive. This design does not require any external springs for locking, as the U bend 22 of self-locking handle 2 provides the necessary compression and extension to allow the latch 1 to seat in a locking slot and secure a caddy 10 in place. Stops 5 extend wider than the sides (or guides) 11 and 12 and prevent the caddy from being inserted farther than it is designed to be.

An EMI cage 7 has two convex fingered sides 16, a front 30 with air flow apertures 31, and two clips 15. The sides 16 are inserted into slots 14 on both top and bottom of the caddy body cross member 23. Tabs 15 come out through slots on the side as shown. The fingers on sides 16 extend above and below the front of caddy 10, and so when caddies are inserted above and below, the EMI cages from each caddy are touching and electrically connected (detailed further below). Screw holes 17 are provided for screws to affix the EMI cage. In an alternate embodiment, the EMI cage clips into the slots 14 without the need for screws.

The caddy body 8 can be injection molded from plastic or can be formed using alternate means and using alternate materials. Caddy body 8 is of unitary construction, which is to say it is made of a single piece of material. The pieces can be injection molded from plastic or can be formed using alternate means and using alternate materials. Recycled plastic minimizes environmental impact and can be more cost-effective than standard materials. The use of plastic in an example embodiment reduces overall weight of the caddy.

In the example embodiment, the caddy body uses PC+ABS (PC+ABS is a thermoplastic that combines the heat resistance of polycarbonate and the flexural strength of ABS. It is suitable for prototyping, tooling and production parts that require high impact strength and reliability.) EMI cage 7 serves as a conductive element and is constructed from electrically conductive material such as metal. Example materials include beryllium copper, aluminium, tinned steel and SS301 (stainless steel). Optical element 6 can be made of simple acrylic, or any light permeable material that is suitable.

FIG. 1B shows the first embodiment of an EMI cage 7, as detailed above, in its separate parts. Here, the tabs 15 have holes 25 which align with holes 17 in the main body 24 of the EMI cage 7. Screws can be used to both assemble and affix the EMI cage to the caddy 8 in an example embodiment. EMI cage 7 serves as a conductive element. Main body 24 of EMI cage 7 and body of tabs 15 are constructed from electrically conductive material such as metal. Example materials include beryllium copper, aluminium, tinned steel, SS301 (stainless steel), etc. In another embodiment, the tabs 15 can be made up of one conductive material (e.g. beryllium copper) which is different from that of main body 24 (e.g. SS301 (stainless steel)).

FIG. 1C illustrates an alternate embodiment of an EMI cage 40. In contrast with EMI cage 7, EMI cage 40 includes a unitary body which can be formed with only 4 bends to a sheet of conductive material, for example. The unitary body includes a central web 43 having a top edge, a bottom edge, a first end, and a second end.

Top flanges 41 and 42 are formed integrally with central web 43 at the top and bottom edges, respectively, and extend in a first direction relative to the central web. Extensions 44 and 45 are integrally formed with the central web at the first and second ends, respectively, and extend in a second direction opposite the first direction. Each include a hole 46, which, when coupled with a caddy, align with mounting features of the caddy. This EMI cage is compatible with the screwless mounting features detailed above. It is also compatible with a conventional caddy utilizing holes to allow for screws to affix the hard drive. In either case, the EMI cage is coupled with a caddy, and one or more of the mounting features of the caddy are used to secure the EMI cage to the caddy. Holes 53 are included which can connect with corresponding features on a caddy during coupling. No other mounting mechanism is required.

In one embodiment, each extension comprises a tab having a substantially rectangular shape. In another embodiment, each extension comprises a tab having a substantially curved or arcuate shape. Extensions are protruding portions, such as tabs, but can be any shape allowing one or more holes 46 to align with a corresponding caddy mounting feature. The top flange, bottom flange, and central web form a substantially C-shaped cross-section in a plane perpendicular to the top edge. In one embodiment, the unitary body is formed by bending a sheet of conductive material, using 4 bends. The extensions are each configured to flex minimally relative to the central web, although rigidity or flexibility can vary in any embodiment, so long as the caddy mounting feature sufficiently affixes the EMI cage. EMI cage 40 serves as a conductive element and is constructed from electrically conductive material such as metal. Example materials include beryllium copper, aluminium, tinned steel, SS301 (stainless steel), etc.

The top and bottom flanges are configured for attachment with one or more electromagnetic interference (EMI) fingers 52, as shown in FIG. 1D. The EMI fingers are made up of electrically conductive material such as metal e.g. beryllium copper, aluminium, tinned steel, SS301 (stainless steel), etc. Here, each set of slot 50 and notch 51 allow for attachment of an EMI finger as shown in FIGS. 1L and 1M. In this embodiment, five sets of slots 50 and notches 51 are used as shown and as detailed further in FIGS. 1J-L below. Alternate embodiments may use greater or fewer EMI fingers.

FIG. 1E shows top, front, left and right views of EMI cage 40. Note that, in this embodiment, tab 45 is sized smaller than tab 44 to accommodate an optical element such as element 6 detailed above. In an embodiment, the EMI cage 40 can be made of conductive material that differs from EMI fingers 52.

An alternate embodiment of a caddy body 8 is illustrated in FIG. 1F. Here, flexible feature 26 is formed as tab 70, having latch 1 and handle 2 affixed as detailed above. Tab 70 is formed, emanating from the substantially linear edge 73, along which the tab is attached and flexes, in a recess 27 in side 11 with connection region 28 as shown. An edge typically refers to a linear boundary or line where two surfaces meet. For a tab formed by a recess (e.g., a rectangular cutout with three sides free and one attached as detailed here), the connection point is the boundary where the tab remains joined to the body. The tab's attachment is a straight line of material continuity. Note that flex is not limited to the connection point, or linear edge, but may occur anywhere along the tab. This edge 73 is illustrated in FIG. 1F with a dashed line. This in contrast to the U-shaped bend formed in a recess, also within side 11, but with connection region attached to the crossmember. This embodiment provides a simpler injection process for manufacturing. FIG. 1G shows another angle of flexible feature 26 relative to crossmember 23. Here, stopping feature 71 prevents flexible feature from moving out of a pre-determined range of motion. Another view can be seen in the cross-sectional view of FIG. 1H. Feature 26 flexes, allowing latch 1 to move sufficiently to engage with and release from a catch. The stopping feature prevents excess movement which may prematurely wear the self-locking handle 2.

FIG. 1I shows the alternate embodiment of caddy 10, which is substantively the same as the embodiment of FIG. 1A, as shown, with sides 11 and 12, optical element 6, and mounting pins 4. The self-locking handle 2 is different, as just detailed. In addition, the second handle 3 is an alternate embodiment. Here, rather than protruding as in FIG. 1A, handle 3, with grip, is formed within cavity 72 of crossmember 23, as detailed in the cutout. This design choice may be deployed in consideration of mold cavity complexity.

FIG. 1J shows caddy 10 with exploded views of EMI cage 40 and EMI fingers 52. Note that each of caddy sides/guides 11 and 12 have a slot pair 53 configured to receive and attach to an EMI finger 52 to provide side EMI shielding (slot pair 53 for side 12 is not visible). Alternate embodiments may include additional slot pairs to accommodate more than one EMI finger per side. FIG. 1K shows EMI cage 40 coupled with caddy body 8 with an exploded view of the EMI fingers 52. FIG. 1L shows EMI cage 40 coupled with caddy body 8 and the fingers 52 in their positions: 5 on the top, 1 on side 11, 1 on side 12 (not visible), and 5 on the bottom (not visible).

FIG. 1M shows the top view of caddy 10 in this embodiment (EMI fingers omitted in this figure). Here it is seen that EMI cage 40 is coupled with caddy body 8. Illustrated are the extensions, tabs 44 and 45, having their holes 46 aligned to and engaged with mounting pins 4 to secure the cage within the caddy. Note that, while the caddy embodiments disclosed herein are screwless, this embodiment of EMI cage 40 is compatible with other caddy designs as well. For example, in a caddy where the mounting feature for securing the hard drive to the caddy utilizes mounting screws, the caddy will have holes positioned to receive those mounting screws. The extensions of EMI cage 40 may be configured to align with those holes once coupled to that caddy type, and to thus receive and engage with a utilized mounting screw. Thus, one or more holes 46 may be configured to align with mounting features including screws and holes, in addition to mounting pins.

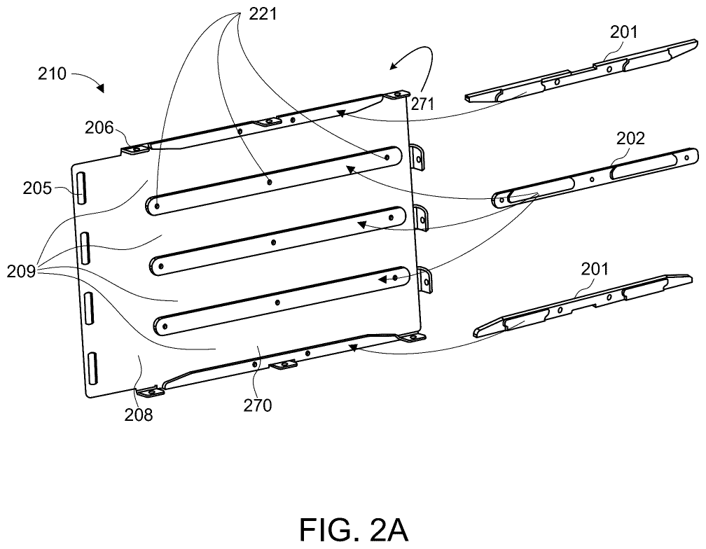

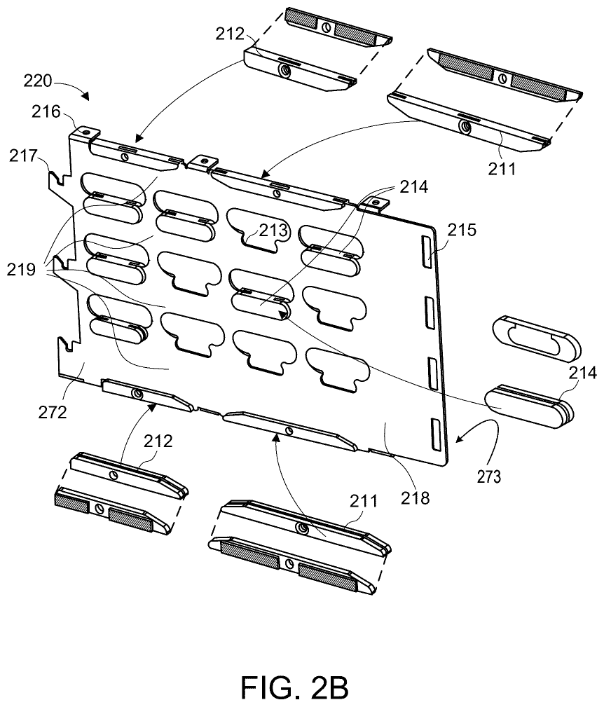

FIGS. 2A and 2B illustrate server chassis plates including a sidewall 210 and a center wall 220 which can be configured to receive a caddy 10 by creating channels 209 and/or 219 for receiving caddy sides/guides 11 and 12. Sidewall 210 is configured to be horizontally symmetric so that it can be used as a left sidewall as shown or flipped horizontally to be used as a right sidewall in one embodiment.

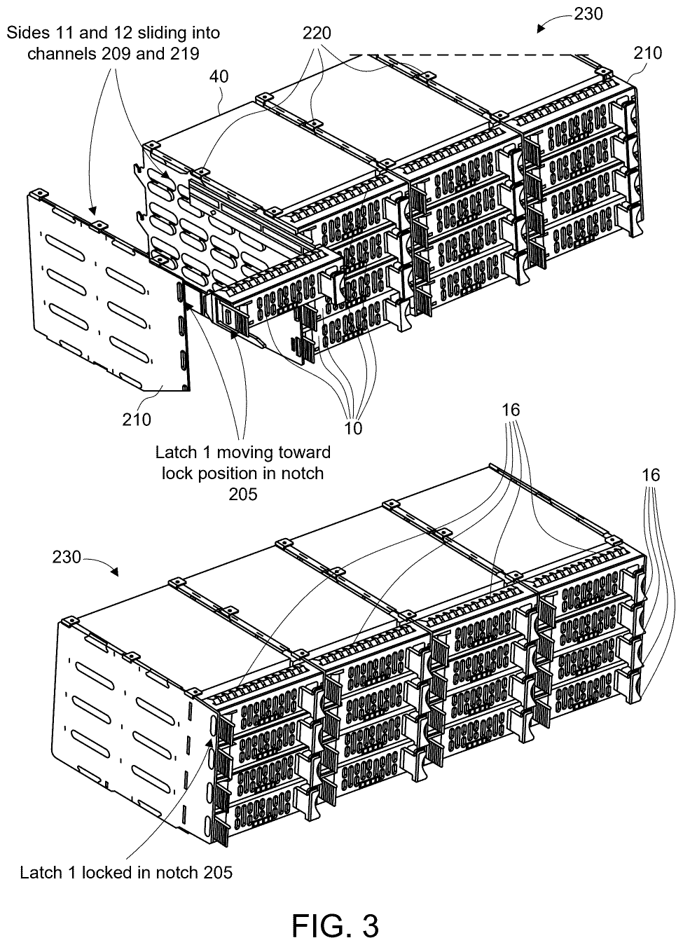

In this example each plate forms 4 channels, 209 or 219, although other embodiments may include different numbers of channels. A column of four caddies (and accordingly four drives) can be accommodated with a pair of sidewalls 210. Eight caddies, in two columns of four, can be accommodated with a pair of sidewalls 210 and one center wall 220. One or more additional columns of caddies may be added by adding one or more additional center walls 220. In the example embodiment, 16 caddies in four columns of four are supported using two sidewalls 210 and three center walls 220 (as depicted in FIG. 3). Sidewalls 210 are compatible with center walls 220, as shown. However, sidewalls 210 may be combined with alternate center walls, and vice versa, in alternate embodiments.

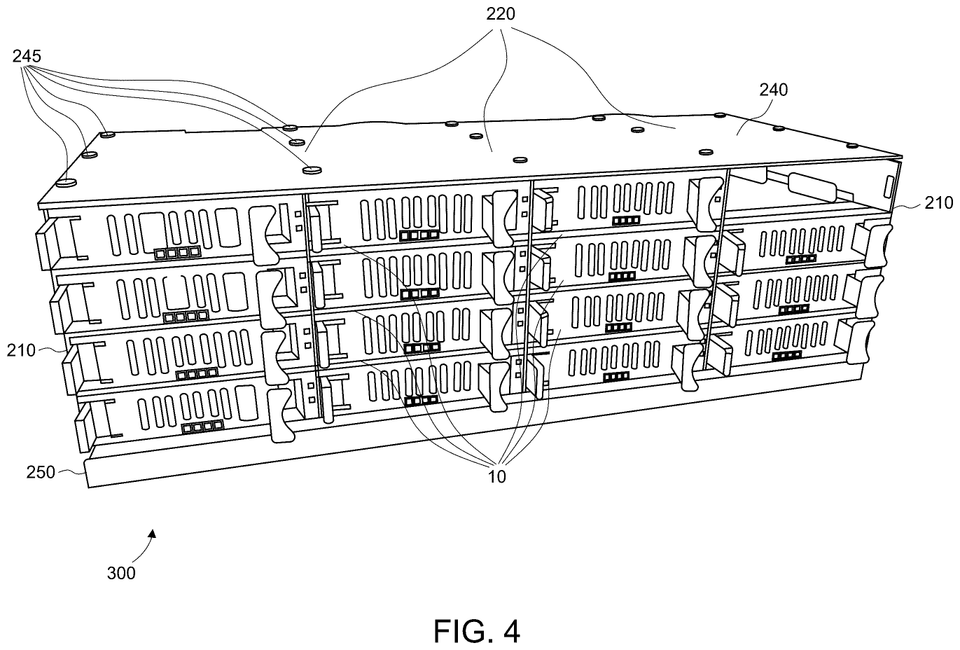

Sidewall 210 is comprised of a metal sidewall plate 208 having an inner side 270, shown, and an outer side 271 opposite inner side 270, not visible. Plate 208 has locking slots or catches 205 to receive the latch (or lock) 1 of the caddy. One side of the caddy, side 11, is sized to fit in the channels 209, which are formed by guides affixed to the inner side of sidewall plate 208. In this example, a top guide 201, bottom guide 201 and three center guides 202 are deployed to form the channels. The guides are plastic. Guide 201 is symmetrical so it can be used as either a top guide or bottom guide. They are affixed to sidewall plate 208 with screws in the holes 221 as shown. Metal tabs 206 are included for attachment to a top, rear, and bottom of an enclosure as part of a server chassis (examples are shown in FIGS. 3 and 4). A caddy inserted into a sidewall 210 will come to rest as its latch 1 having been depressed upon contact with the front edge of plate 208 is released into its original position upon arriving in a catch 205. A stopping edge, or stop, 5 on the caddy 10 may be included which abuts one of guides 201 or 202 as applicable in various embodiments, and prevents the caddy from traveling further upon insertion, preventing damage to a printed circuit board with connectors for receiving the drives in the caddies (not shown).

A center wall 220 comprises a center wall plate 218 which can be affixed with dual guides 211 and 212. Guides 211 and 212 are symmetrical and can be deployed as either top or bottom guides as shown. The dual guides straddle the center wall plate 218 to provide guide edges for top and bottom channels 219. Middle guides 214 can be inserted into cutouts 213 to provide top and bottom guide edges for the center channels 219. A cross section is shown bisecting each guide 211, 212, and 214. Middle guides 214 do not require any screws. Because they are dual sided, the guides 211, 212, and 214 form four channels 219 on the side (first side 272) as shown, and four symmetrical channels on the opposite side (second side 273) of center wall 220 as well.

As with sidewall 210, a caddy inserted into a center wall 220 will come to rest as its latch 1 having been depressed upon contact with the front edge of plate 218 is released into its original position upon arriving in a catch 215. A stop 5 on the caddy 10 may be included which abuts one of guides 214 (or one of guides 211 as adapted various alternative embodiments) and prevents the caddy from traveling further upon insertion, preventing damage to a printed circuit board with connectors for receiving the drives in the caddies (not shown).

Top and bottom guides 211 and 212 can optionally be screwed into plate 218 via screw holes or alternatively will be secured in place when plate 218 is secured to a top and bottom plate via tabs 216. Notches 217 are deployed for receiving a PCB for connecting to drives carried in inserted caddies 10.

In the example embodiment the plastic parts are made of PC/ABS and the metal parts are MS Steel. PC/ABS (polycarbonate/acrylonitrile-butadiene-styrene terpolymer blend) is a thermoplastic alloy of (PC) polycarbonate and (ABS) acrylonitrile-butadiene-styrene. Both PC/ABS materials are well known amorphous plastics. Alloying these two materials enhances processability and provides non-halo flame retardancy. Polycarbonates used in engineering are strong, tough materials, and some grades are optically transparent. They are easily worked, molded, and thermoformed. MS Steel, or mild steel, is a ferrous metal made from iron and carbon. It is a low-priced material with properties that are suitable for most general engineering applications. Low carbon mild steel has good magnetic properties due to its high iron content; it is therefore defined as being ‘ferromagnetic’.

FIG. 3 illustrates a portion of a server chassis 230 comprising two sidewalls 210 (one left and one right) and three center walls 220. These 5 walls form four enclosures with guideways formed by the channels 209 and 219 for receiving caddies 10. Shown on top are 12 caddies already inserted into channels with drives 40 loaded within them. An empty caddy is shown being inserted for illustration. The sides 11 and 12 of the caddy serve as guides gliding in channels 209 and 219 as shown. Latch 1 is moving towards its lock position in notch 205. Shown below is the portion of a server chassis 230 with all 16 caddies 10 and drives 40 inserted. Note that latch 1 is now locked in notch 205.

In alternate embodiments, the sides 11 and 12 of a caddy can be different widths. By making corresponding changes to guides 201, 202, 211, 212 and/or 214, the channels 209 will be different widths than the channels 219. In this manner, the caddy 10 and this portion of the server chassis 230 become unidirectional, as the caddy can only be inserted in one orientation. The plates 208 may be symmetrical although the guides affixed to them are not the same size.

As shown in FIG. 1A, caddy 10 may be equipped with a stopping edge 5 on the top and/or bottom of crossmember 23. These can prevent over-insertion (in combination with the auto-locking mechanism or other over-insertion methods) by abutting with one or more of guides 201, 202, 211, 212 and/or 214, as applicable, as described above. These stopping edges may be symmetrical or can be made at different depths. By making corresponding changes to guides 201, 202, 211, 212 and/or 214, the channels 209 will have guide placement at different depths those in the channels 219. In this manner, the caddy 10 and this portion of the server chassis 230 become unidirectional, as the caddy can only be inserted in one orientation, since a longer stop will prematurely hit the shallower depth guide if inserted incorrectly.

Note that the top EMI cage fingers 16 can be seen extending up from the top four caddies. The EMI cage fingers 16 from each caddy are electrically connected from top to bottom. The lower caddies will have lower EMI cage fingers extending down. In FIG. 4 an enclosure 300 is formed by attaching a conductive top 240 and a conductive bottom 250 to the portion of server chassis 230. In this example screws 245 are used to secure the top 240 and bottom 250 to the side walls 210 and the three center walls 220. Thus, the EMI shield for the enclosure is formed by the individual EMI cages 7 along with the side and center walls 210 and 220 and top 240 and bottom 250. Note that the caddies shown in FIG. 4 do not have their EMI cages installed, but the same top and bottom configuration is compatible with chassis 230 in FIG. 3.

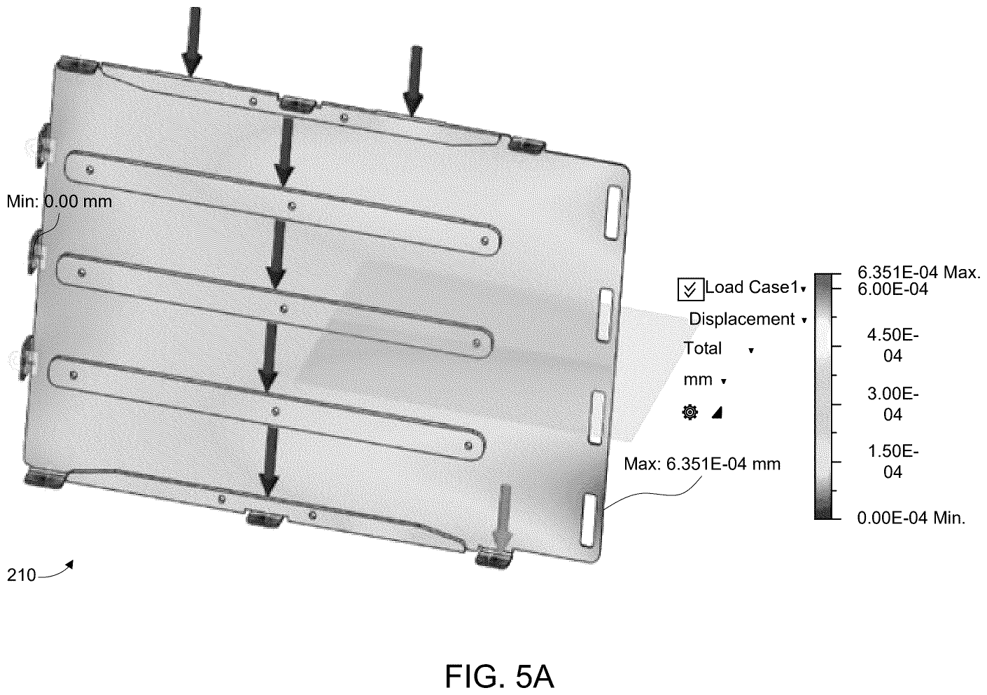

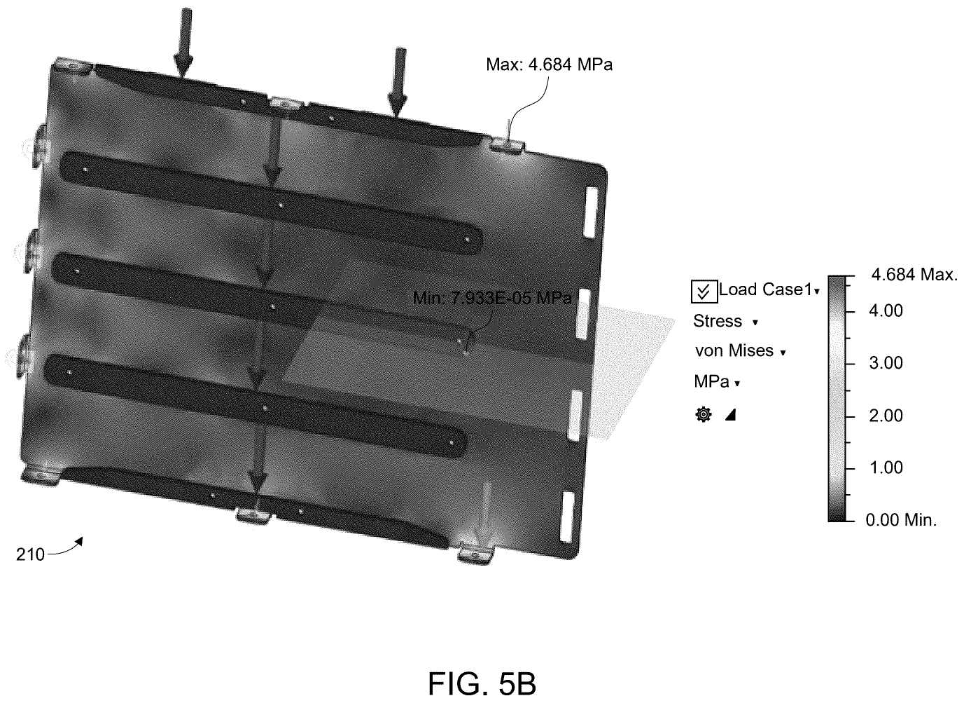

FIGS. 5A and 5B show results of strength test analysis of the sidewall 210. FIG. 5A shows the amount of deflection when a load of 1 kg on each plastic guide was applied. The amount of deviation, 0.0004 mm is negligible. FIG. 5B shows a von Mises stress generated when particular amount of load has been applied to the body, here it is 4.684 MPa.

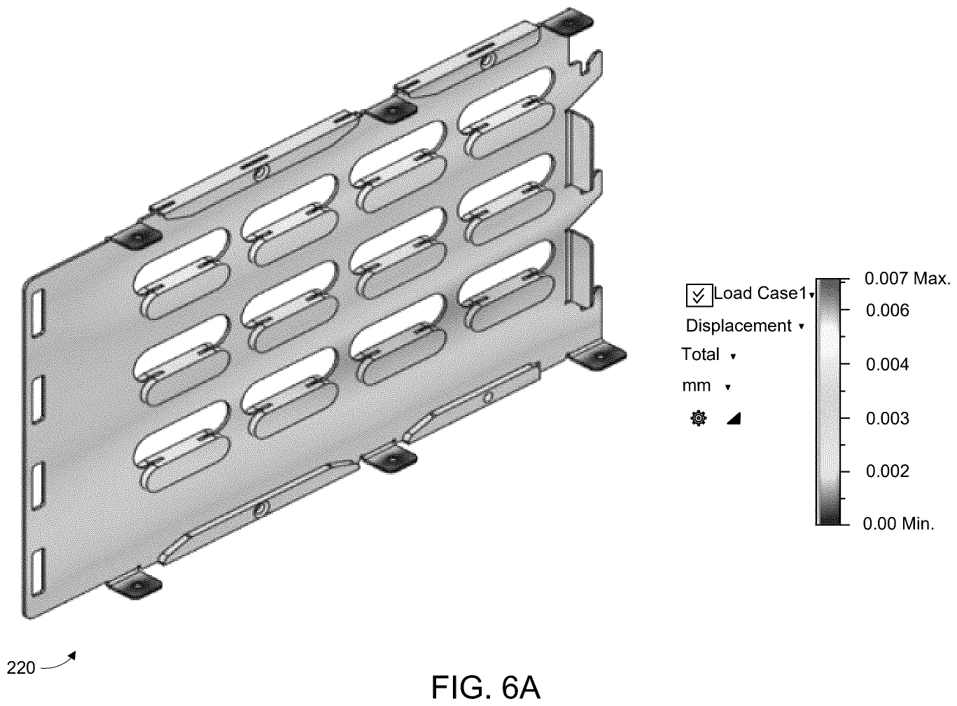

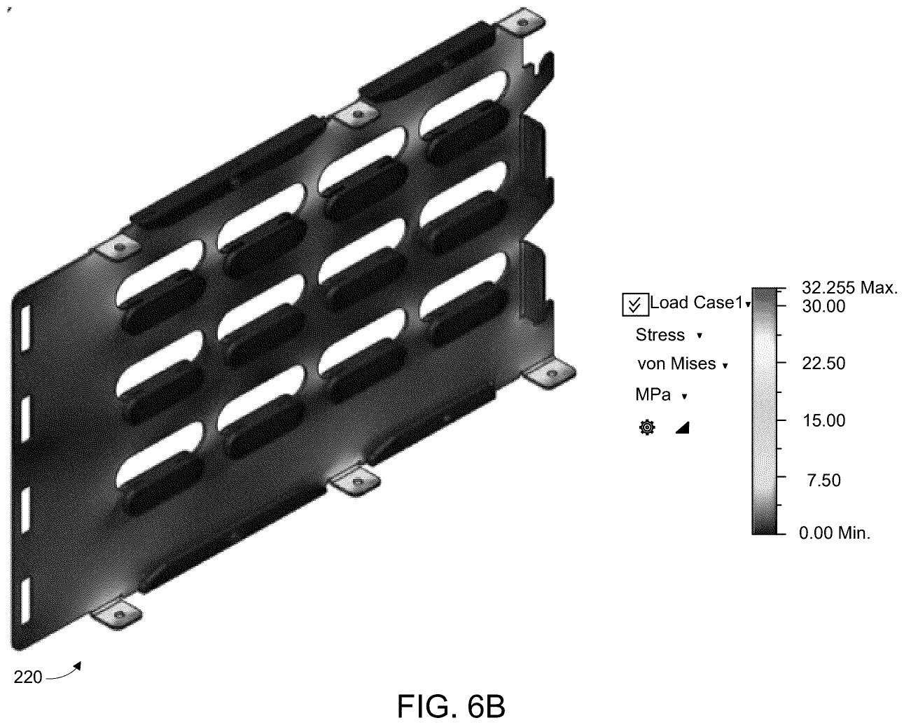

FIGS. 6A and 6B show results of strength test analysis of the center wall 220. FIG. 6A shows the deflection of 0.007 mm when 1 kg of load is applied to guides (row wise—for 4 guide 1 Kg distributed load). FIG. 6B shows the von mises stress generated due to load of 32.25 MPa. While a typical drive weighs 650-720 grams, the load used in the simulations considered a drive weight of 1 kg as a safety factor. In both cases the materials selected were sufficiently strong for the purpose of containing fully weighted caddies 10. The use of plastic guides has an additional advantage of absorbing vibrations caused by high-speed rotation in hard disk drives.

The foregoing description of the implementations of the present techniques and technologies has been presented for the purposes of illustration and description. This description is not intended to be exhaustive or to limit the present techniques and technologies to the precise form disclosed. Many modifications and variations are possible in light of the above teaching. It is intended that the scope of the present techniques and technologies are not limited by this detailed description. The present techniques and technologies may be embodied in other specific forms without departing from the spirit or essential characteristics thereof. Accordingly, the disclosure of the present techniques and technologies is intended to be illustrative and not limiting. Therefore, the spirit and scope of the appended claims should not be limited to the foregoing description. In U.S. applications, only those claims specifically reciting “means for” or “step for” should be construed in the manner required under 35 U.S.C. § 112 (f).

What is claimed is:

1. A caddy for housing a storage drive within a server chassis, the caddy comprising a caddy body to support the storage drive, the caddy body comprising:
a crossmember having a first end and a second end;
first and second guiding sides extending from the crossmember to connect to the storage drive, each of the first and second guiding sides having a first and second width, respectively, and at least one guiding side including one or more mounting pins for engaging with a cavity in the storage drive;
a flexible feature integrally formed in the caddy body, the flexible feature defined by a recess in the caddy body, the recess at least partially surrounding the flexible feature such that the flexible feature is integrally attached to the caddy body at a connection region, wherein the flexible feature is configured to flex relative to the caddy body about the connection region;
a latch operatively coupled to the flexible feature, the latch being movable between an extended position and a retracted position, wherein the flexible feature is configured to resiliently deform in response to an applied force on the latch, thereby allowing the latch to displace from the extended position to the retracted position, and to return the latch to the extended position upon release of the applied force;
a first handle fixed to the flexible feature, proximate to the first end of the crossmember, the first handle movable responsive to an applied force in concert with displacement of the flexible feature; and
a second handle fixed to the crossmember proximate to the second end of the crossmember.

2. The caddy of claim 1, further comprising one or more stopping edges, wherein each stopping edge extends from at least one of the first or second guiding sides and the stopping edge extension is placed at a predetermined distance from one of the one or more mounting pins to determine the depth of a housed storage drive within the server chassis.

3. The caddy of claim 1, further comprising a conductive element, adaptable to form part of an electromagnetic interference shield, the conductive element configured to couple with the crossmember of the caddy body.

4. The caddy of claim 3 wherein the conductive element is comprised of two or more parts.

5. The caddy of claim 1, further comprising an optical element to receive source light at a first end and display the source light at a second end, wherein one of the guiding sides comprises a recess shaped to receive and house the optical element, the first end of the optical element aligning with a first element of the one of the guiding sides and the second end of the optical element proximate with the second end of the guiding side and protruding through the crossmember, the source light visible at an external face of the crossmember.

6. The caddy of claim 1, wherein the connection region comprises a substantially linear edge, and the flexible feature extends from the linear edge to form a tab configured to flex about the linear edge.

7. The caddy of claim 6, further comprising a stopper feature disposed to prevent the flexible feature from moving outside a range of motion.

8. The caddy of claim 7, wherein the stopper feature is configured to allow the flexible feature to flex relative to the caddy body such that the latch retracts sufficiently to engage with a catch.

9. The caddy of claim 1, wherein the connection region comprises a U-shaped bend, and the flexible feature extends from the U-shaped bend to form a loop configured to flex about the U-shaped bend.

10. The caddy of claim 1, wherein the second handle protrudes outward from the crossmember.

11. The caddy of claim 1, wherein the second handle is formed at least partially around a cavity defined in the crossmember.

12. The caddy of claim 1, wherein the caddy body is unitary.

13. The caddy of claim 1, wherein the crossmember comprises one or more apertures facilitating airflow.

14. The caddy of claim 3, wherein the crossmember and conductive element comprise one or more apertures facilitating airflow, one or more of the conductive element apertures overlapping with one or more of the crossmember apertures.

15. The caddy of claim 1, wherein the first and second widths are different.

16. The caddy of claim 2, comprising a stopping edge of a first depth on the first side of the crossmember, and a stopping edge of a second depth, different than the first depth, on the second side of the crossmember.

17. An apparatus for housing one or more columns of one or more of the caddy of claim 1, comprising:
a first sidewall comprising:
a plate having an inner side and an outer side;
a plurality of first guides affixed to the inner side of the plate, the plurality of first guides defining a set of first channels, each first channel sized to receive the first guiding side of a caddy; and
a set of first locking slots, each first locking slot deployed in one of the set of first channels to receive and engage the latch of a caddy; and
a second sidewall comprising:
a plate having an inner side and an outer side; and
a plurality of second guides affixed to the inner side of the plate, the plurality of second guides defining a set of second channels, each second channel sized to receive the second guiding side of a caddy;
wherein the first sidewall and the second sidewall are positioned such that the inner side of the plate of the first sidewall faces the inner side of the plate of the second sidewall, and each channel of the first set of channels is aligned with a corresponding channel of the second set of channels to support one or more columns of caddies between the first sidewall and the second sidewall.

18. The apparatus of claim 17, further comprising at least one center wall positioned between the first sidewall and the second sidewall, the at least one center wall having a first side and a second side, each of the first side and the second side having a plurality of third guides and a plurality of fourth guides affixed thereto forming a set of third channels and a set of fourth channels, respectively, and a plurality of second locking slots, each second locking slot deployed in one of the set of fourth channels to receive and engage the latch of a caddy, wherein each third channel is aligned with and dimensioned to correspond to a second channel, and each fourth channel is aligned with and dimensioned to correspond to a first channel, to support a plurality of columns of caddies interspersed between the first and second sidewalls and the at least one center wall.

19. The apparatus of claim 17, wherein each of the set of first channels and the set of second channels have essentially the same width to receive first and second guiding sides of essentially the same width.

20. The apparatus of claim 17, wherein each of the set of first channels differ in width from each of the set of second channels to receive first and second guiding sides of differing widths.

21. The apparatus of claim 17, wherein the plates of the first and second sidewalls are symmetrical.

22. The apparatus of claim 17, where the first and second sidewalls are symmetrical.

23. The apparatus of claim 18, wherein the at least one center wall includes a plurality of cutouts and a plurality of double-sided guides, each double-sided guide positioned within a cutout and protruding from both the first side to form the plurality of third guides and the second side to form the plurality of fourth guides, the plurality of double-sided guides defining both the sets of third and fourth channels.

24. The apparatus of claim 17, wherein the first sidewall plate and the second sidewall plate are made of metal, and the plurality of first and second guides are made of plastic.

25. The apparatus of claim 23, wherein the at least one center wall is made of metal, and the plurality of double-sided guides are made of plastic.

26. The apparatus of claim 17, further comprising:
a conductive top plate attached to the first and second sidewalls and conductively coupled to the plates of the first and second sidewalls; and
a conductive bottom plate attached to the first and second sidewalls and conductively coupled to the plates of the first and second sidewalls;
wherein each caddy of the one or more columns is equipped with a conductive element, adaptable to form part of an electromagnetic interference shield, the plates of the first and second sidewalls are conductive, each of the conductive elements of the caddies abutting with one of the top plate or the conductive element of a caddy above and one of the bottom plate or the conductive element of a caddy below, and the top plate, bottom plate, side plates of the first and second sidewalls, and conductive elements of the caddies combine to form the electromagnetic interference shield.

27. A server chassis comprising an apparatus of claim 17 and a plurality of the caddy of claim 1.

28. A device configured for coupling with a hard drive caddy having at least one mounting feature, the device comprising:
a unitary body formed of a conductive material, the unitary body including:
a central web having a top edge, a bottom edge, a first end, and a second end;
a top flange integrally formed with the central web at the top edge and extending in a first direction relative to the central web;
a bottom flange integrally formed with the central web at the bottom edge and extending in the first direction relative to the central web; and
an extension integrally formed with the central web at the first end and extending in a second direction opposite the first direction, the extension including a hole; and
wherein:
the central web, top flange, bottom flange, and extension are integrally formed as a single piece; and
the hole is configured to align with one of the at least one mounting features of a coupled hard drive caddy.

29. The device of claim 28, wherein the unitary body further comprises a second extension integrally formed with the central web at the second end and extending in the second direction, the second extension including a second hole configured to align with a second mounting feature of a coupled hard drive caddy.

30. The device of claim 28, wherein the hole is operable with a mounting pin affixed to a coupled hard drive caddy.

31. The device of claim 28, wherein the extension comprises a tab having a substantially rectangular shape.

32. The device of claim 28, wherein the top flange, bottom flange, and central web form a substantially C-shaped cross-section in a plane perpendicular to the top edge.

33. The device of claim 28, wherein the unitary body is formed by bending a sheet of conductive material.

34. The device of claim 29, wherein the first-mentioned extension and the second extension are each configured to flex minimally relative to the central web.

35. The device of claim 28, wherein the top flange and the bottom flange are configured for attachment with one or more electromagnetic interference (EMI) fingers.
